(19) United States
(12) Patent Application Publication
(10) Pub. No.: US 2002/0068375 A1
(43) Pub. Date: Jun. 6, 2002

(54) Structure of a semiconductor module and method of manufacturing the same

(76) Inventor: Takashi Hosaka, Chiba-shi (JP)

Correspondence Address: ADAMS & WILKS, 31st FLOOR, 50 BROADWAY, NEW YORK, NY, 10004, US

(21) Appl. No.: 09/966,721

(22) Filed: Sep. 27, 2001

(30) Foreign Application Priority Data
Oct. 30, 2000 (JP) 2000-331079

(51) Int. Cl. H01L 21/00

(52) U.S. Cl. 438/57

(57) ABSTRACT

There is provided a semiconductor module that can be easily manufactured and has a photosensitive element. A minute unevenness portion is formed over the entirety or a portion of the region except for a light receiving portion in a mold for forming a module. Thus, a minute unevenness portion is formed over the entirety or a portion of the region except for the light receiving portion on the surface of the module. This module is immersed into a solution containing a light shielding material to deposit the film containing the light shielding material in the unevenness portion. The module in which the film is deposited is thermal-treated, and thus the module in which the film containing the light shielding material is deposited over the entirety or a portion of the region except for the light receiving portion can be manufactured.

### BACKGROUND OF THE INVENTION

1. Field of the Invention

The present invention relates to a module including a photosensitive element and a method of manufacturing the same.

2. Description of the Related Art

A conventional structure of a module including a photosensitive element is shown in FIG. 2. That is, in the module shown in FIG. 2, a photosensitive element, that is, a light receiving element 22, a control IC 23 for processing a signal from the light receiving element 22, and an attachment chip part 24 are mounted on a substrate 21. As the light receiving element 22, there is, for example, a photodiode, a solar battery, or the like. As the chip part 24, there is a resistor, a capacitor, or an inductor. The above element and part are covered with a package rein 25. As this package rein 25, a resin which can maximize the amount of light entering the light receiving element 22, that is, a resin that is transparent with respect to the entering light is selected. The above element and part are protected by the package resin 25 from a mechanical shock and an environment in which the module is set.

A light receiving portion 26 of the module is formed with a lens shape in order to maximize the convergence of light into the light receiving element 22.

Generally, when elements except for the light receiving element 22 are irradiated with light, it is likely to cause a noise. Thus, as shown in FIG. 2, these elements are covered with the metal case 27. This metal case 27 covers the surface of the module except for the light receiving portion 26.

The metal case 27 must be formed corresponding to the module. When this metal case 27 is manufactured, a large number of processes such as bending, welding, and punching of a metal plate, must be performed. Thus, a manufacturing cost becomes considerably higher. Also, the metal case and the module must be formed in separate processes, and thus spending on manufacturing facility becomes substantial. Further, since a process for attaching the metal case to the module must be added thereafter, the number of processes is greatly increased. This causes substantial increase in a cost.

### SUMMARY OF THE INVENTION

In order to solve the above problems, according to the present invention, a minute unevenness portion is formed on a surface of a region except for a light receiving portion in a mold for forming a module. Then, when the module is to be formed using this mold, the module in which the region except for the light receiving portion becomes a minute unevenness portion is formed. This module is immersed into a liquid containing a light shielding material to deposit the light shielding material only on the minute unevenness portion thus formed. The resultant module is thermal-treated to cure it, and thus a layer of the light shielding material is formed in the region except for the light receiving portion. Therefore, a state is obtained such that an internal element except for the region of the light receiving portion is not irradiated with light.

### BRIEF DESCRIPTION OF THE DRAWINGS

In the accompanying drawings:

FIGS. 1A to 1E show a method of manufacturing a semiconductor module of the present invention; and

FIG. 2 shows a structure of a conventional semiconductor module.

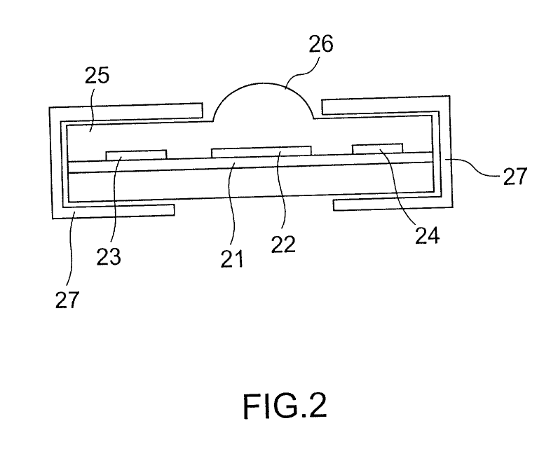

### DETAILED DESCRIPTION OF THE PREFERRED EMBODIMENTS

The present invention is to provide a simple method of preventing light irradiation to a portion that should not receive such irradiation of light, in a module including a photosensitive element.

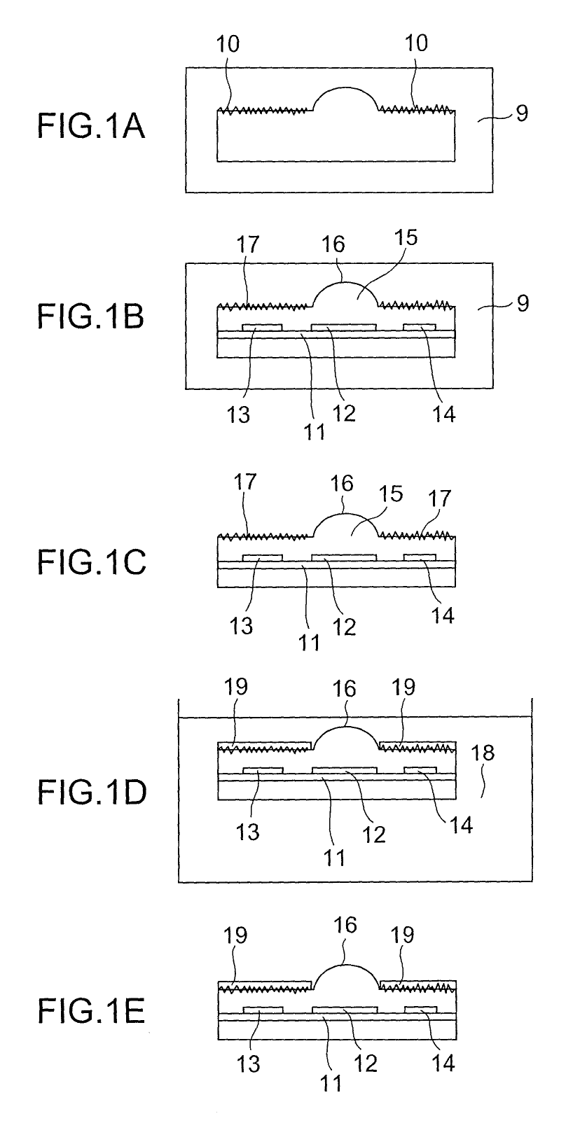

FIGS. 1A to 1E show a manufacturing method of the present invention. That is, as shown in FIG. 1A, a minute unevenness portion 10 is formed on the surface of a region except for a region that becomes a light receiving portion 16 in a mold 9 for forming a module. A size of the unevenness portion 10 is from 0.01 micrometer to 1000 micrometer. The light receiving portion 16 has a smaller size than that of the unevenness portion 10 and a smooth surface. Next, as shown in FIG. 1B, a substrate 11 on which a light receiving element 12, a control IC 13, a chip part 14, and the like are mounted is located into the mold 9 of FIG. 1B. After that, a package resin 15 is poured into the mold 9 and cured. Thus, as shown in FIG. 1C, a module surface in a region except for a portion through which light travels to reach a photosensitive element, that is, the light receiving portion 16, has a minute unevenness portion 17.

Next, as shown in FIG. 1D, the resultant module of FIG. 1C is immersed into a solution 18 containing a light shielding material. As the light shielding material, for example, there is a carbon particle material, a polyimide material, an epoxy material, or the like. When the module is immersed into such a solution, the light shielding material grows thicker in a portion of the module in which the minute unevenness portion 17 is formed, and thus a film 19 containing the light shielding material is deposited. Since the light receiving portion 16 has a s smooth surface, the film 19 containing the light shielding material is hardly or not at all deposited. This module is thermal-treated at a temperature of 50 to 150° C. to cure the film 19. Thus, as shown in FIG. 1E, the film 19 containing the light shielding material can be selectively deposited in the region except for the light receiving portion 16.

As described above, since the light shielding film is deposited on the module surface except for the light receiving portion, light does not enter the module from the region except for the light receiving portion. In addition, since the process is very simple and a material cost becomes lower, a manufacturing cost and the material cost can be greatly reduced in comparison with the case where the metal case is used.

What is claimed is:

1. A module comprising:
a photosensitive element; and
a film containing a materials for shielding light, which is formed on a surface of a region except for a light receiving portion in a module surface through which light reaches the photosensitive element.

2. A method of manufacturing a module, comprising the steps of:
forming a module using a module mold in which an unevenness portion is formed on a surface of at least a portion of a region except for a light receiving portion; and then
immersing the module into a solution containing a light shielding material to selectively deposit a film containing the light shielding material on the unevenness portion.

3. A method of manufacturing a module according to claim 2, wherein the unevenness portion has a size of 0.01 micrometers to 1000 micrometers.

4. A method of manufacturing a module, comprising the steps of:
forming a module using a module mold in which an unevenness portion is formed on a surface of at least a portion of a region except for a light receiving portion; then
immersing the module into a solution containing a light shielding material to selectively deposit a film containing the light shielding material on the unevenness portion; and
thermal-treating the module at a temperature of 50° C. to 150° C. to cure the film containing the light shielding material.
